(19) United States
(12) Patent Application Publication
(10) Pub. No.: US 2009/0159942 A1
(43) Pub. Date: Jun. 25, 2009

(54) Image Sensor and Method for Manufacturing the Same

(76) Inventor: Il Ho Song, Cheongju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/264,298

(22) Filed: Nov. 4, 2008

(30) Foreign Application Priority Data
Dec. 21, 2007 (KR) 10-2007-0135888
Aug. 25, 2008 (KR) 10-2008-0082909

(51) Int. Cl. H01L 31/00; H01L 21/00

(52) U.S. Cl. 257/292; 438/98; 257/E31.001; 257/E21.001

(57) ABSTRACT

An image sensor can include a readout circuitry, a metal interconnection, a metal layer, and an image sensing device. The metal interconnection can be formed over the readout circuitry and the metal layer can be formed over the metal interconnection. The image sensing device can be formed over the metal layer. The metal layer can be formed through a low temperature deposition method at a low temperature.

### CROSS-REFERENCE TO RELATED APPLICATIONS

The present application claims the benefit under 35 U.S.C. §119 of Korean Patent Application No. 10-2007-0135888, filed Dec. 21, 2007 and Korean Patent Application No. 10-2008-0082909, filed Jul. 28, 2008, which are hereby incorporated by reference in their entirety.

### BACKGROUND

An image sensor is a semiconductor device for converting an optical image into an electric signal. The image sensor may be roughly classified as a charge coupled device (CCD) image sensor or a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light, called Airy disk.

As an alternative to overcome this limitation, an attempt of forming a photodiode using amorphous silicon (Si), or forming a readout circuitry in a silicon (Si) substrate using a method such as wafer-to-wafer bonding, and forming a photodiode on and/or over the readout circuitry has been made (referred to as a “three-dimensional (3D) image sensor). The photodiode is connected with the readout circuitry through a metal interconnection.

In the wafer-to-wafer bonding, a bonding force problem may occur.

In addition, since both the source and the drain of the transfer transistor are heavily doped with N-type impurities, a charge sharing phenomenon occurs. When the charge sharing phenomenon occurs, the sensitivity of an output image is reduced and an image error may be generated.

Also, because a photo charge does not readily move between the photodiode and the readout circuitry, a dark current is generated and/or saturation and sensitivity is reduced.

### BRIEF SUMMARY

Embodiments of the present invention relate to an image sensor and a manufacturing method thereof that employ a vertical type photodiode to enhance physical and electrical contact between the vertical type photodiode and a readout circuitry.

Embodiments relate to an image sensor and a manufacturing method thereof that can inhibit the occurrence of charge sharing while increasing a fill factor.

Embodiments relate to an image sensor and a manufacturing method thereof that minimize a dark current source and inhibit reduction in saturation and sensitivity by providing a swift movement path for a photo charge between a photodiode and a readout circuitry.

According to an embodiment an image sensor is provided that can include: a readout circuitry on a first substrate; a metal interconnection on the readout circuitry; a metal layer on the metal interconnection; and an image sensing device on the metal layer, wherein the metal layer is deposited at a low temperature.

According to another embodiment a method for manufacturing an image sensor can include: forming a readout circuitry on a first substrate; forming a metal interconnection on the readout circuitry; forming a metal layer deposited at a low temperature on the metal interconnection; and forming an image sensing device on the metal layer.

### BRIEF DESCRIPTION OF THE DRAWINGS

FIG. 1 shows a cross-sectional view of an image sensor in accordance with an embodiment of the present invention.

FIGS. 2-8 illustrate a method for manufacturing an image sensor in accordance with an embodiment of the present invention.

FIG. 9 shows a cross-sectional view of a readout circuitry portion of an image sensor in accordance with another embodiment of the present invention.

### DETAILED DESCRIPTION

An image sensor and a method for manufacturing an image sensor in accordance with embodiments of the present invention will be described in detail with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

In addition, it is to be understood that the figures and descriptions of embodiments of the present invention have been simplified to illustrate elements that are relevant for a clear understanding of the invention, while eliminating, for purposes of clarity, other elements that may be well known. Those of ordinary skill in the art will recognize that other elements may be desirable and/or required in order to implement the present invention. However, because such elements are well known in the art, and because they do not facilitate a better understanding of the present invention, a discussion of such elements is not provided herein.

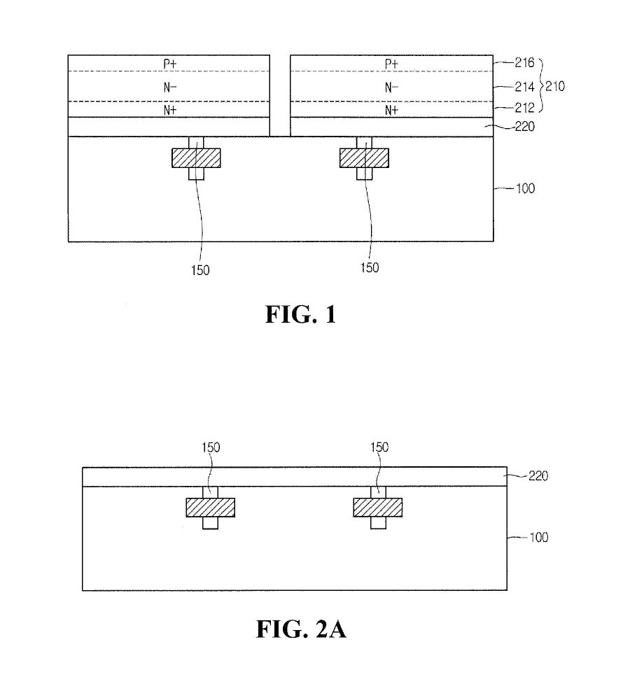

As illustrated in example FIG. 1, an image sensor in accordance with an embodiment of the present invention can include: readout circuitry (not shown) formed on a first substrate 100; metal interconnection 150 formed on and connected to the readout circuitry; a metal layer 220 on a the metal interconnection 150; and an image sensing device 210 on the metal layer 220. The metal layer 220 can be formed at a low temperature.

The image sensing device 210 can be a photodiode, a photogate or any combination thereof. Although embodiments describe a photodiode as being formed in a crystalline semiconductor layer, the photodiode is not limited thereto. For example, the photodiode can be formed in an amorphous semiconductor layer.

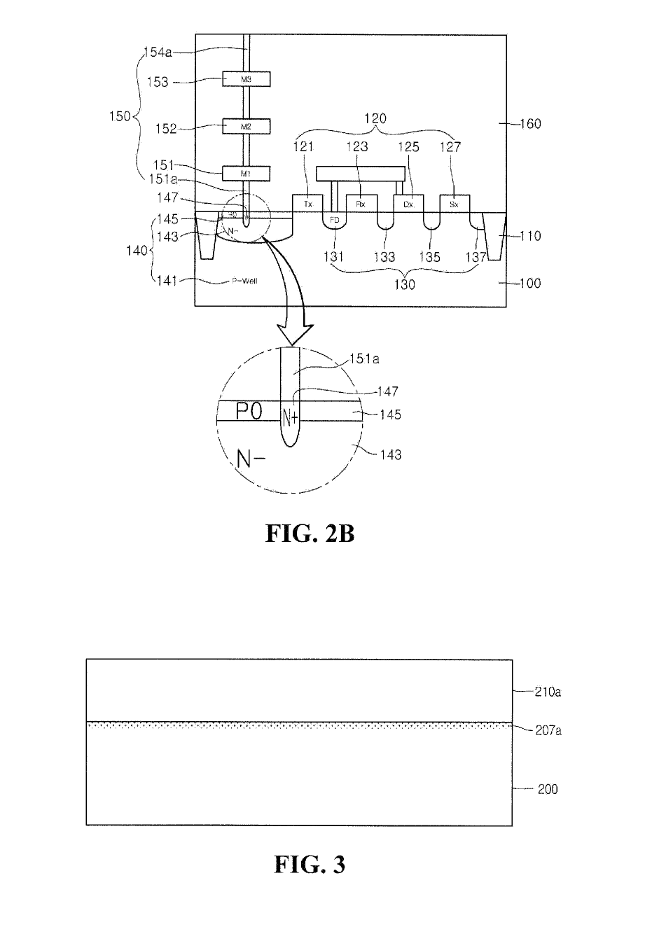

Hereinafter, a method for manufacturing an image sensor according to an embodiment will be described with reference to FIGS. 2 to 8. FIG. 2A shows a simplified cross-sectional view of a first substrate 100 on which a metal interconnection 150 is formed, and FIG. 2B provides a detailed view according to one embodiment for the first substrate 100 of FIG. 2A.

Referring to FIG. 2B, a method for manufacturing an image sensor can include providing a first substrate 100 on which a metal interconnection 150 and readout circuitry 120 are formed. The first substrate 100 can be, but is not limited to, a second conduction type substrate. In an embodiment, a device isolation layer 110 can be formed in the second conduction type first substrate 100 to define an active region. Readout circuitry 120 including at least one transistor can be formed on the active region. In one embodiment, the readout circuitry can include a transfer transistor (Tx) 121, a reset transistor (Rx) 123, a drive transistor (Dx) 125 and a select transistor (Sx) 127. Ion implantation regions 130 including a floating diffusion region (FD) 131, and source/drain regions 133, 135, and 137 of respective transistors can be formed. In accordance with further embodiments, a noise removal circuit can be formed in order to maximize sensitivity.

The forming of readout circuitry 120 on the first substrate 100 can include forming an electrical junction region 140 in first substrate 100, and forming a first conduction type connection region 147 interposed between and electrically connected to metal interconnection 150 and electrical junction region 140.

The electrical junction region 140 can be but is not limited to, a PN junction. For example, the electrical junction region 140 can include a first conduction type ion implantation layer 143 formed on a second conduction type well 141 (or a second conduction type epitaxial layer), and a second conduction type ion implantation layer 145 formed on first conduction type ion implantation layer 143. For example, the PN junction 140 can be, but is not limited to, a P0 (145)/N−(143)/P-(141) junction such as shown in FIG. 2B.

According to an embodiment, a device is designed such that there is a potential difference between the source and drain at the sides of transfer transistor (Tx) 121 so that a photo charge can be fully dumped. Accordingly, a photo charge generated from the photodiode is fully dumped to the floating diffusion region so that the sensitivity of an output image can be maximized.

Accordingly, the electrical junction region 140 can be formed in first substrate 100 where the readout circuitry 120 is formed to allow the generation of a potential difference between the source and the drain of the transfer transistor (Tx) 121, so that a photo charge can be fully dumped.

Hereinafter, a dumping structure of a photo charge in accordance with an embodiment is described in detail.

Unlike a node of floating diffusion (FD) 131, which is an N+ junction, the PNP junction 140, which is the electrical junction region 140 and to which an applied voltage is not fully transferred, is pinched-off at a predetermined voltage. This voltage is called a pinning voltage, which depends on the doping concentrations of a P0 region 145 and an N− region 143.

Specifically, an electron generated from the photodiode 210 moves to the PNP junction 140, and is transferred to the node of floating diffusion (FD) 131 and converted into a voltage when the transfer transistor Tx 121 is turned on.

Since a maximum voltage value of the P0/N−/P-junction 140 becomes a pinning voltage, and a maximum voltage value of the node of floating diffusion (FD) 131 becomes a threshold voltage Vₜₕ of V_{dd-Rx} 123, an electron generated from photodiode 210 in the upper portion of a chip can be fully dumped to the node of floating diffusion (FD) 131 without charge sharing by implementing a potential difference between the sides of transfer transistor (Tx) 131.

Meaning, according to an embodiment, the P0/N−/P-well junction, not an N+/P-well junction, is formed in the first substrate 100 to allow a+voltage to be applied to N−region 143 of the P0/N−/P-well junction and a ground voltage to be applied to the P0 region 145 and the P-well 141 during a 4-Tr active pixel sensor (APS) reset operation, so that a pinch-off is generated at the P0/N−/P-well double junction at a predetermined voltage or more as in a bipolar junction transistor (BJT) structure. This is called the pinning voltage. Therefore, a potential difference is generated between the source and the drain of transfer transistor (Tx) 121 to inhibit a charge sharing phenomenon during the on/off operations of transfer transistor (Tx) 121.

Therefore, unlike a case where a photodiode is simply connected to an N+ junction, limitations such as saturation reduction and sensitivity reduction can be avoided.

After forming the P0/N−/P-junction 140, a, first conduction type connection region 147 can be formed between the photodiode and the readout circuitry to provide a swift movement path of a photo charge, so that a dark current source is minimized, and saturation reduction and sensitivity reduction can be inhibited.

For this purpose, a first conduction type connection region 147 for ohmic contact (for example, N+ region 147) can be formed on the surface of P0/N−/P-junction 140. The N+region 147 can be formed to extend through the P0 region 145 and contact the N− region 143.

In order to inhibit the first conduction type connection region 147 from becoming a leakage source, the width of the first conduction type connection region 147 can be minimized. Therefore, in accordance with certain embodiments, a plug implant can be performed after a via hole for a first metal contact 151a is etched. However, embodiments are not limited thereto. For example, an ion implantation pattern (not shown) can be formed and the first conduction type connection region 147 can then be formed using the ion implantation pattern as an ion implantation mask.

A reason for locally and heavily doping only a contact forming portion with N-type impurities in the above described embodiment is to facilitate ohmic contact formation while minimizing a dark signal. In case of heavily doping the entire transfer transistor source, a dark signal may be increased by a Si surface dangling bond.

An interlayer dielectric 160 can be formed on the first substrate 100. The metal interconnection 150 can be formed extending through interlayer dielectric 160 and electrically connected to first conduction type connection region 147. The metal interconnection 150 can include but is not limited to the first metal contact 151a, a first metal 151, a second metal 152, a third metal 153, and a fourth metal contact 154a.

Referring again to FIG. 2A, a metal layer 220 can be formed on the first substrate 100 so that metal layer 220 contacts the metal interconnection 150.

In certain embodiments, the metal layer 220 on the first substrate 100 can be a low-k metal layer. For example, the metal layer 220 can be but is not limited to at least one selected from the group consisting of chrome (Cr), aluminum (Al) and copper (Cu). In such embodiments, since a low-k metal layer is interposed between a substrate on which a photodiode is formed and a substrate on which a readout circuitry is formed, the bonding force between these two substrates can be enhanced. According to an embodiment, the metal layer 220 on the first substrate 100 can be a metal layer deposited in a low temperature range of about 150-170° C. by a photochemical deposition. If the deposition is performed at a temperature of less than 150° C., dissociation for photochemical deposition may not occur, whereas if the deposition temperature exceeds 170° C., thermal damage may occur.

For example, the metal layer 220 can be formed of, but is not limited to, gold (Au).

In a specific embodiment, (CH₃)2Au[CH(COCF₃)₂] can be used as the source for the photochemical deposition of Au. The Au can be deposited at a low temperature in a unit of several μm. Since the photochemical deposition is performed by dissociating an organic metal compound using light, Au can be deposited at a temperature equal to or less than about 160° C. Advantageously, Au has a good adhesive force to a metal interconnection formed of a metal such as tungsten (W) and a crystalline semiconductor layer.

That is, in accordance with embodiments, since a metal layer, that can be deposited at a low temperature, is interposed between a substrate over which a photodiode is formed and a substrate over which a readout circuitry is formed, an adhesive force of the metal layer to the overlying crystalline semiconductor layer as well as the underlying metal interconnection can be enhanced.

Referring to FIG. 3, a crystalline semiconductor layer 210a can be formed on a second substrate 200. In accordance with embodiments, a photodiode 210 can be formed in the crystalline semiconductor layer 210a. Accordingly, the image sensing device adopts a 3-dimensional (3D) image sensor arrangement with the image sensing device located on the readout circuitry to raise a fill factor, and is formed inside the crystalline semiconductor layer so that defects inside the image sensing device can be reduced.

In an embodiment, the crystalline semiconductor layer 210a can be formed on the second substrate 200 using epitaxial growth. Then, hydrogen ions can be implanted between the second substrate 200 and the crystalline semiconductor layer 210a to form a hydrogen ion implantation layer 207a interposed between the second substrate 200 and the crystalline semiconductor layer 210a. In one embodiment, the implantation of the hydrogen ions can be performed after the ion implantation for forming photodiode 210.

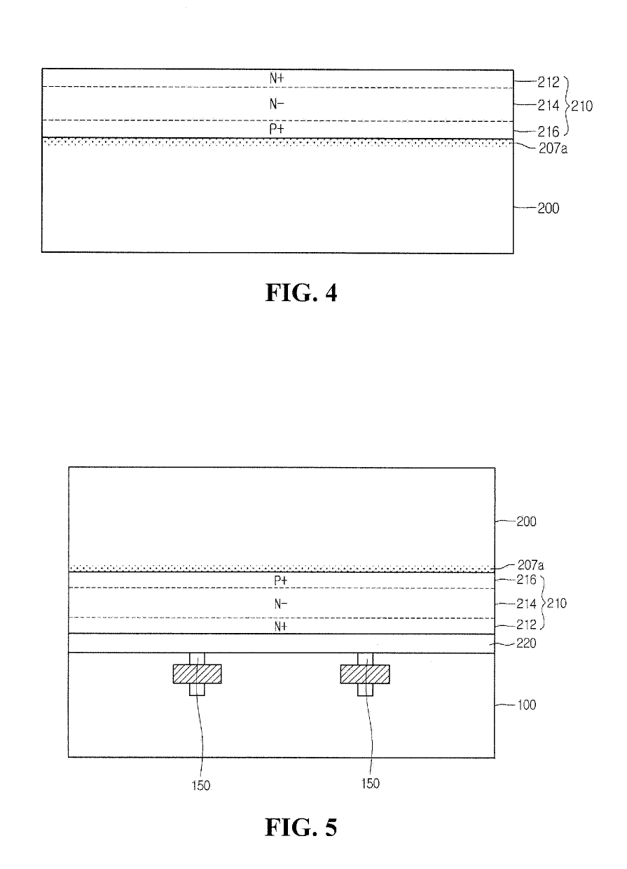

Referring to FIG. 4, the photodiode 210 can be formed in the crystalline semiconductor layer 210a using ion implantation. For example, a second conduction type conduction layer 216 can be formed in the lower portion of crystalline semiconductor layer 210a and may contact the hydrogen ion implantation layer 207a. The second conduction type conduction layer 216 can be a high concentration P-type conduction layer 216 can be formed in the crystalline semiconductor layer 210a by performing a first blanket-ion implantation on the entire surface of second substrate 200 without a mask. For example, the second conduction type conduction layer 216 can be formed to have a junction depth of less than about 0.5 μm from a lower portion of the crystalline semiconductor layer 210a.

After that, a first conduction type conduction layer 214 can be formed on the second conduction type conduction layer 216 by performing a second blanket-ion implantation on the entire surface of second substrate 200 without a mask. For example, the low concentration first conduction type conduction layer 214 can be formed at a junction depth ranging from about 1.0 μm to about 2.0 μm.

The first conduction type conduction layer 214 can be formed thicker than the second conduction type conduction layer 216, such that a charge storing capacity can be enhanced. That is, the capacity that can store photoelectrons can be enhanced by forming N-type conduction layer 214 thicker than P-type conduction layer 216 to increase the area of N-type conduction layer 214.

In a further embodiment, a high concentration first conduction type conduction layer 212 can be formed on the first conduction type conduction layer 214 by performing a third blanket-ion implantation on the entire surface of second substrate 200 without a mask so that first conduction type conduction layer 214 can contribute to ohmic contact. For example, high concentration first conduction type conduction layer 212 can be formed at a junction depth ranging from about 0.05 μm to about 0.2 μm.

Next, referring to FIG. 5, the first substrate 100 and the second substrate 200 are bonded such that photodiode 210 contacts metal interconnection 150. Before the first substrate 100 and the second substrate 200 are bonded to each other, the bonding can be performed by increasing the surface energy of a surface to be bonded through activation by plasma.

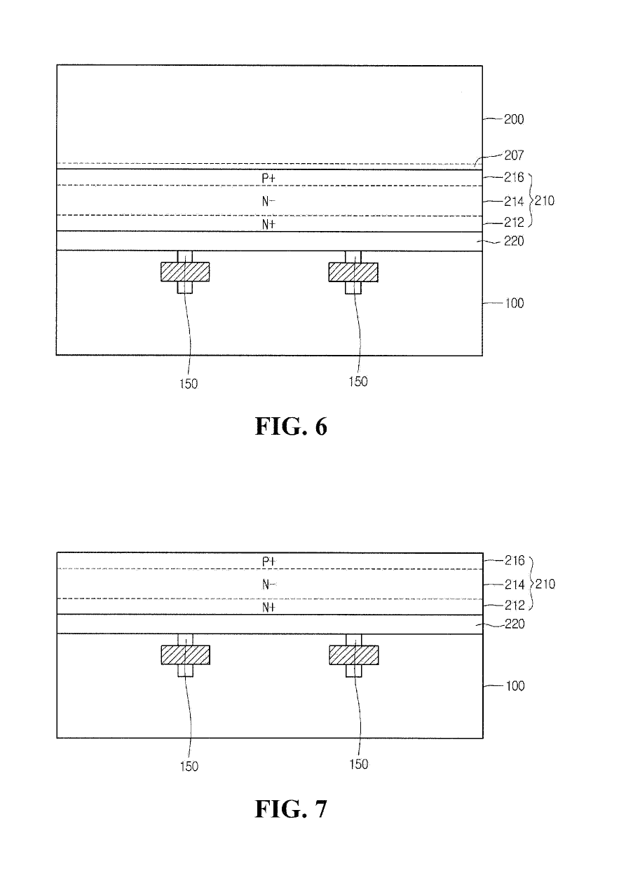

Referring to FIG. 6, the hydrogen ion implantation layer 207a can be changed into a hydrogen gas layer by performing a heat treatment on the second substrate 200.

Referring to FIG. 7, a portion of the second substrate 200 can then be removed with the photodiode 210 remaining on the first substrate 100 so that photodiode 210 can be exposed. The removal of second substrate 200 can be performed using a cutting apparatus such as a blade.

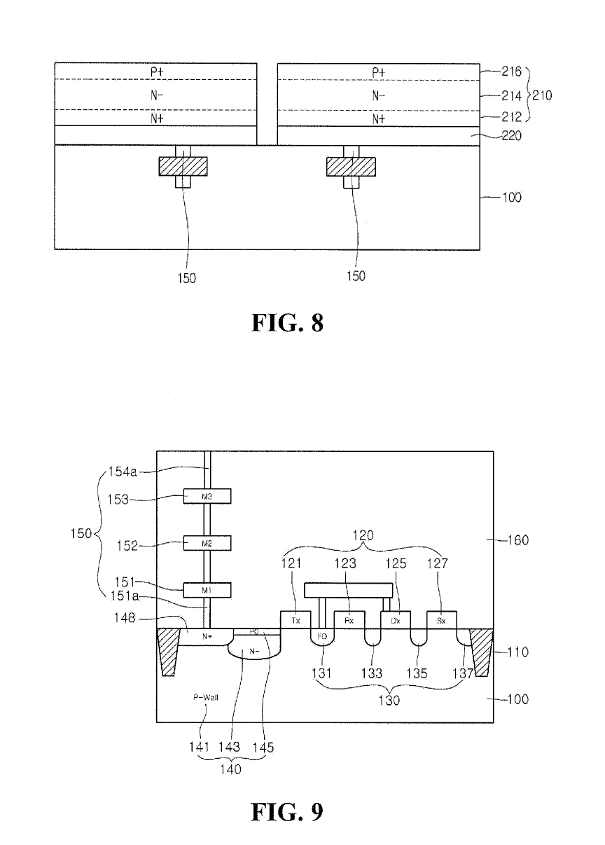

Referring to FIG. 8, an etching process separating the photodiode 210 for each unit pixel can then be performed. Then a ground metal formation process, a color filter process, etc. may be performed to complete the image sensor manufacturing process.

FIG. 9 is a cross-sectional view of an image sensor, and specifically provides a detailed view of the first substrate according to another embodiment. These structures can be used in place of those described with respect to FIG. 2B.

As illustrated in FIG. 9, an image sensor in accordance with an embodiment can include a first conduction type (N+) connection region 148 formed at a side of the electrical junction region 140.

According to an embodiment, the N+ connection region 148 can be formed adjacent the P0/N−/P-junction 140. The process of forming the N+ connection region 148 and a M1C contact 151a may provide a leakage source because the device operates with a reverse bias applied to P0/N−/P-junction 140 and so an electric field (EF) can be generated on the Si surface. A crystal defect generated during the contact forming process inside the electric field serves as a leakage source.

Also, in the case where the N+connection region 148 is formed on the surface of P0/N−/P-junction 140, an electric field can be generated due to N+/P0 junction 148/145. This electric field also serves as a leakage source.

Therefore, according to one embodiment, the first contact plug 151a is formed in an active region not doped with a P0 layer but including the N+ connection region 148. Then, through the N+ connection region 148, the first contact plug 151a is connected with the N− junction 143.

In accordance with embodiments, the electric field is not generated on the Si surface, and a dark current of a 3D integrated CIS can be reduced.

Although embodiments relate generally to a complementary metal oxide semiconductor (CMOS) image sensor, such embodiments are not limited to the same and may be readily applied to any image sensor utilizing a photodiode.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
readout circuitry on a first substrate;
a metal interconnection connected to the readout circuitry;
a low temperature-deposited metal layer on the metal interconnection; and
an image sensing device on the metal layer.

2. The image sensor according to claim 1, wherein the metal layer is formed by a photochemical method.

3. The image sensor according to claim 1, wherein the metal layer comprises gold.

4. The image sensor according to claim 1, further comprising an electrical junction region on the first substrate and electrically connected to the readout circuitry.

5. The image sensor according to claim 4, wherein the electrical junction region comprises:
a first conduction type ion implantation region on the first substrate; and
a second conduction type ion implantation region on the first conduction type ion implantation region.

6. The image sensor according to claim 4, wherein the readout circuitry comprises a transistor, wherein the electrical junction region is disposed at a side of the transistor such that a potential difference exists between a source and a drain of the transistor.

7. The image sensor according to claim 6, wherein the transistor comprises a transfer transistor and an ion implantation concentration of the source of the transfer transistor is lower than an ion implantation concentration of a floating diffusion region.

8. The image sensor according to claim 4, further comprising a first conduction type connection region between the electrical junction region and the metal interconnection.

9. The image sensor according to claim 8, wherein the first conduction type connection region is disposed at an upper portion of the electrical junction region and electrically connected to the metal interconnection.

10. The image sensor according to claim 8, wherein the first conduction type connection region is disposed at a side of the electrical junction region and electrically connected to the metal interconnection.

11. A method for manufacturing an image sensor, comprising:
forming a readout circuitry on a first substrate;
forming a metal interconnection on the readout circuitry;
forming a metal layer deposited at a low temperature on the metal interconnection; and
forming an image sensing device on the metal layer.

12. The method according to claim 11, wherein the forming of the metal layer comprises depositing a metal at the low temperature of between about 150-170° C.

13. The method according to claim 1 1, wherein the metal layer comprises gold.

14. The method according to claim 13, wherein the forming of the metal layer comprises performing photochemical deposition.

15. The method according to claim 14, wherein the photochemical deposition is performed using (CH₃)2AU[CH(COCF₃)₂] as a source.

16. The method according to claim 11, further comprising forming an electrical junction region on the first substrate and electrically connected to the readout circuitry.

17. The method according to claim 16, wherein the forming of the electrical junction region comprises:
forming a first conduction type ion implantation region in the first substrate; and
forming a second conduction type ion implantation region over the first conduction type ion implantation region.

18. The method according to claim 16, further comprising forming a first conduction type connection region between the electrical junction region and the metal interconnection.

19. The method according to claim 18, wherein the first conduction type connection region is formed at an upper portion of the electrical junction region and electrically connected to the metal interconnection.

20. The method according to claim 18, wherein the first conduction type connection region is formed at a side of the electrical junction region and electrically connected to the metal interconnection.
